(19) United States
(12) Patent Application Publication
(10) Pub. No.: US 2015/0060120 A1
(43) Pub. Date: Mar. 5, 2015

(54) TOUCH PANEL

(71) Applicant: SAMSUNG ELECTRO-MECHANICS CO., LTD., Suwon-Si (KR)

(72) Inventor: Jang Ho PARK, Suwon-Si (KR)

(73) Assignee: SAMSUNG ELECTRO-MECHANICS CO., LTD.

(21) Appl. No.: 14/473,154

(22) Filed: Aug. 29, 2014

(30) Foreign Application Priority Data
Aug. 29, 2013 (KR) 10-2013-0103192
Aug. 25, 2014 (KR) 10-2014-0111024

(51) Int. Cl. G06F 3/044; H05K 1/11; H05K 1/09; H05K 1/02; H05K 1/03

(52) U.S. Cl. CPC G06F 3/044; H05K 1/0296; H05K 1/03; H05K 1/09; H05K 1/117; H05K 2201/10151
USPC 174/257

(57) ABSTRACT

There is provided a touch panel including a substrate; and electrode parts including a plurality of electrodes formed on the substrate, wherein the electrode parts include a plurality of conductive lines formed in a mesh pattern and have different aperture ratios for a plurality of respective regions of the substrate.

### CROSS-REFERENCE TO RELATED APPLICATION

This application claims the benefit of Korean Patent Application No. 10-2013-0103192 filed on Aug. 29, 2013, and Korean Patent Application No. 10-2014-0111024 filed on Aug. 25, 2014 with the Korean Intellectual Property Office, the disclosure of which is incorporated herein by reference.

### BACKGROUND

The present disclosure relates to a touch panel.

In general, a touchscreen apparatus such as a touchscreen, a touch pad, or the like, a device user interface attached to a display apparatus to provide an intuitive user interface, has recently been widely used in various electronic apparatuses such as cellular phones, personal digital assistants (PDAs), navigation apparatuses, and the like. Particularly, as demand for smartphones has recently increased, the use of touchscreens capable of providing various user interface methods in a limited form factor has correspondingly increased.

Touchscreens used in portable apparatuses may mainly be divided into resistive type touchscreens and capacitive type touchscreens, according to a method of sensing a touch implemented therein. Here, capacitive type touchscreens have advantages in that they have a relatively long lifespan and various types of touches and gestures may be easily used therewith, such that the use thereof has increased. Particularly, capacitive type touchscreens may more easily allow for a multi-touch interface to be realized, as compared with resistive type touchscreens, such that they are widely used in apparatuses such as smartphones, and the like.

Capacitive type touchscreens include a plurality of electrodes having a predetermined pattern and forming a plurality of nodes in which changes in capacitance are generated by touches. In the plurality of nodes distributed on a two-dimensional plane, changes in self-capacitance or in mutual-capacitance may be generated by touches. Coordinates of a touch may be calculated by applying a weighted average method, or the like, to changes in capacitance generated in the plurality of nodes.

In a touch panel according to the related art, a sensing electrode recognizing a touch is generally formed of indium tin oxide (ITO). However, ITO is relatively expensive and is not particularly competitive in terms of price, since indium used as a raw material thereof is a rare earth metal. In addition, indium reserves are expected to be depleted within the next decade, such that indium may not be easily supplied in the future. Research into technology for forming electrodes using opaque conductive lines for the reasons mentioned above has been conducted. Here, such electrodes formed of the conductive lines may have better conductivity than that of the ITO or conductive polymer and the supply thereof may be smoothly performed. However, in order to use conductive lines as electrodes for a touchscreen, transparency and invisibility should be increased and terminal resistance should be suppressed.

Patent Document 1 of the following related art document discloses increasing an area of a sensor electrode and decreasing a distance at an edge portion in order to reinforce output coordinates of the edge portion in the capacitive type touchscreen, but this configures the electrode using the ITO, and does not disclose implementing the electrode using the conductive lines, in which the conductive lines of an effective region and an a bezel region have different opening ratios.

### RELATED ART DOCUMENT

[Patent Document] Korean Patent Laid-Open Publication No. 10-2013-0044432

### SUMMARY

An exemplary embodiment in the present disclosure may provide a touch panel having improved transparency in the touch panel in an effective region, preventing the disconnection of conductive lines in a bezel region, and decreasing a resistance value by allowing the conductive lines formed in a mesh pattern in the effective region and the bezel region to have different opening ratios.

According to an exemplary embodiment in the present disclosure, a touch panel may include: a substrate; and electrode parts having a plurality of electrodes formed on the substrate, wherein the electrode parts include a plurality of conductive lines formed in a mesh pattern and have different opening ratios for a plurality of respective regions of the substrate.

### BRIEF DESCRIPTION OF THE DRAWINGS

The above and other aspects, features and other advantages in the present disclosure will be more clearly understood from the following detailed description taken in conjunction with the accompanying drawings, in which:

FIG. 1 is a perspective view illustrating the exterior of an electronic apparatus including a touch panel according to an exemplary embodiment in the present disclosure;

FIG. 2 is a front view of the touch panel according to an exemplary embodiment in the present disclosure;

FIG. 3 is a front view illustrating the touch panel according to an exemplary embodiment of FIG. 2 in greater detail.

FIG. 4 is a cross-sectional view of the touch panel according to an exemplary embodiment in the present disclosure;

FIG. 5 is a partially-enlarged view of conductive lines according to an exemplary embodiment in the present disclosure; and

FIGS. 6 through 8 are perspective views illustrating touch panels according to various exemplary embodiments in the present disclosure.

### DETAILED DESCRIPTION

Hereinafter, embodiments in the present disclosure will be described in detail with reference to the accompanying drawings.

The disclosure may, however, be embodied in many different forms and should not be construed as being limited to the embodiments set forth herein. Rather, these embodiments are provided so that this disclosure will be thorough and complete, and will fully convey the scope of the disclosure to those skilled in the art.

In the drawings, the shapes and dimensions of elements may be exaggerated for clarity, and the same reference numerals will be used throughout to designate the same or like elements.

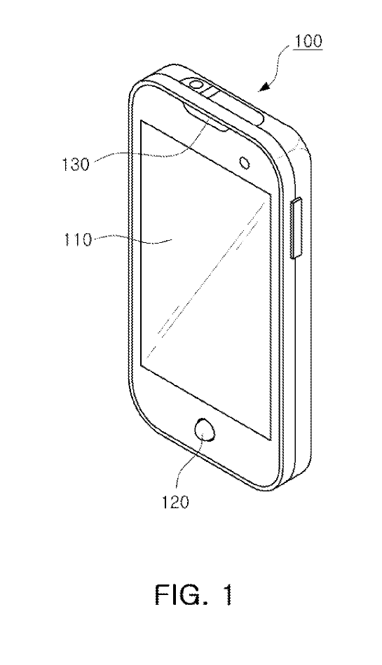

FIG. 1 is a perspective view illustrating the exterior of an electronic apparatus including a touch panel according to an exemplary embodiment in the present disclosure.

Referring to FIG. 1, an electronic apparatus 100 according to the present embodiment may include a display apparatus 110 for outputting an image, an input unit 120, an audio unit 130 for audio output, and a touchscreen apparatus (not shown) integrated with the display apparatus 110, wherein a touch panel may be included in the touchscreen apparatus.

The touchscreen apparatus may include a substrate and a touch panel having a plurality of electrodes provided on the substrate. Also, the touchscreen apparatus according to an exemplary embodiment in the present disclosure may include a controller integrated circuit (touch sensing apparatus) including a capacitance detection circuit detecting changes in capacitance generated in the plurality of electrodes, an analog-to-digital conversion circuit converting an output signal from the capacitance detection circuit into a digital value, an operation circuit determining a touch by using data converted as the digital value, and the like.

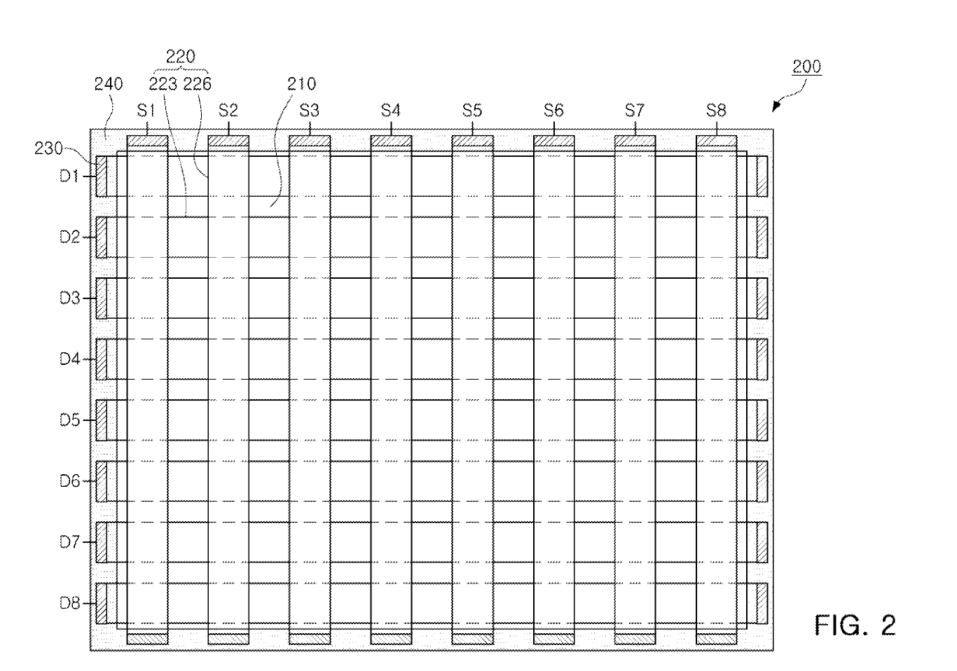

FIG. 2 is a front view of the touch panel according to an exemplary embodiment in the present disclosure.

Referring to FIG. 2, a touch panel 200 according to the present exemplary embodiment may include a substrate 210, electrode parts 220 provided on the substrate 210, pad parts 230 including a plurality of pads connected to the electrode parts 220, respectively, and a bezel portion 240.

Although not illustrated in FIG. 2, the pad parts 230 connected to the electrode parts 220, respectively, may be electrically connected to a flexible printed circuit board attached to one end of the substrate 210 through wirings and bonding pads. A controller integrated circuit is mounted on the circuit board to detect a sensing signal generated in the electrode part 220 and determine a touch from the sensing signal.

Therefore, the substrate 210 may be formed of a material for a film such as polyethylene terephtalate (PET), polycarbonate (PC), polyethersulfone (PES), polyimide (PI), polymethylmethacrylate (PMMA), cyclo-olefin polymers (COP), or the like, soda glass, or tempered glass.

The electrode parts 220 may include the first electrodes 223 extending in an X-axis (first axial) direction and the second electrodes 226 extending in a Y-axis (second axial) direction. The first electrodes 223 and the second electrodes 226 may intersect with each other on both surfaces of the substrate 210, or on different substrates 210. In the case in which the first electrodes 223 and the second electrodes 226 are both formed on one surface of the substrate 210, predetermined insulating layers may be partially formed in intersections between the first electrodes 223 and the second electrodes 226.

The apparatus electrically connected to the electrode parts 220 to sense a touch may detect changes in capacitance generated in the electrode parts 220 according to a touch applied thereto and sense the touch therefrom. The first electrode 223 may be connected to channels D1 to D8 in the controller integrated circuit to thereby have a predetermined driving signal applied thereto, and the second electrode 226 may be connected to channels S1 to S8 to be used for the touch sensing apparatus to detect sensing signals. In this case, the controller integrated circuit may detect the changes in capacitance generated between the first electrode 223 and the second electrode 226 to thereby obtain the sensing signals and may be operated in a scheme in which driving signals are sequentially applied to each of the first electrodes 223 and simultaneously detects the changes in capacitance in the second electrodes 226.

When the driving signals are applied to the first electrodes 223 through the channels D1 to D8, mutual capacitance may be generated between the first electrodes 223 to which the driving signals are applied and the second electrodes 226. In the case in which a touch object contacts the touch panel, the change in capacitance may be generated in the mutual capacitance, wherein the change in capacitance may be in proportion to an area of the touch object.

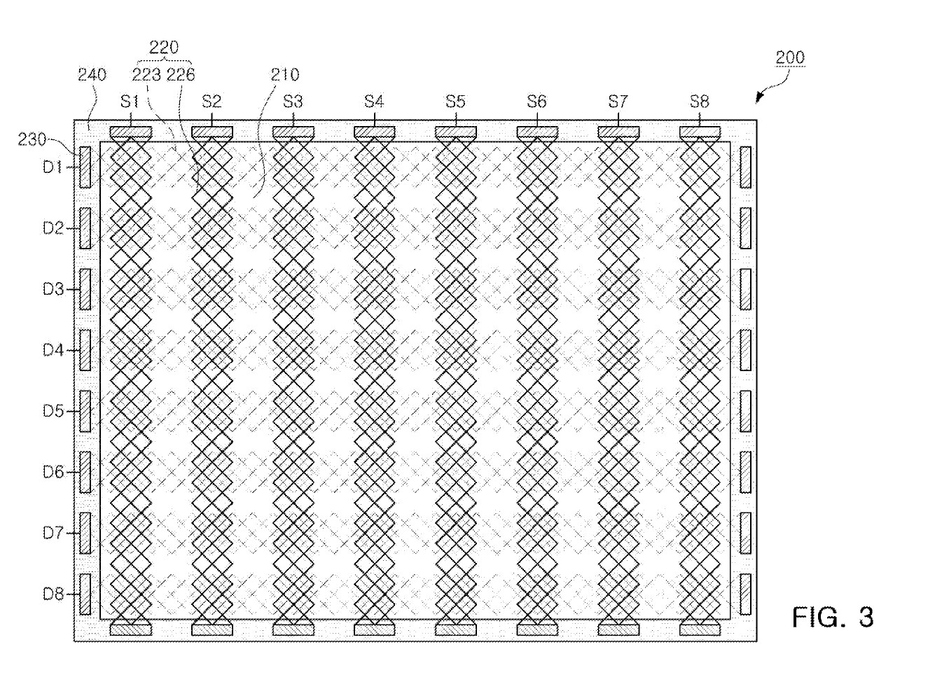

FIG. 3 is a view illustrating the touch panel according to an exemplary embodiment of FIG. 2 in greater detail.

Referring to FIG. 3, the electrode parts 220 may be formed of conductive lines, wherein the conductive lines forming the electrode parts 220 may have a net or mesh pattern. In the case in which the conductive lines are formed in the net or the mesh pattern, a phenomenon in which a patterning mark is visible in a region in which an indium-tin oxide electrode conventionally exists may be decreased and transparency of the touch panel may be improved.

Although FIG. 3 shows a case in which the conductive lines forming the electrode parts 220 are formed in a rhomboid or rectangular pattern, the pattern of the conductive lines is not limited thereto, and the pattern of the conductive lines according to the present disclosure may include a range apparently or easily deducted by those skilled in the art such as a hexagon, an octagon, a diamond pattern, a random pattern, and the like.

The conductive lines forming the electrode parts 220 may be manufactured by using one of silver (Ag), aluminium (Al), chromium (Cr), nickel (Ni), molybdenum (Mo), and copper (Cu), or alloys thereof. In the case in which the electrode parts 220 are manufactured of a metal, a resistance value of the electrode may be decreased, such that conductivity and detecting sensitivity thereof may be improved.

The pad part 230, the wirings for electrically connecting the pad part 230 and the circuit board to each other, the bonding pad, and the like may be typically formed of an opaque metal material, wherein in order to visually shield the pad part 230, the wiring, and the bonding pad, the bezel portion 240 may be formed in a predetermined region of the substrate 210.

The bezel portion 240 may be formed in a region of the substrate 210 except for a region (a view region) to which an image is output or a region (an active region) to which the touch is applied in a display apparatus having the touch of the user applied thereto and formed integrally with the touch panel, wherein the bezel portion 240 may be generally positioned on edges of the substrate 210. Hereinafter, the region having the bezel portion 240 formed thereon is referred to as a bezel region and other regions are referred to as effective regions for convenience of explanation.

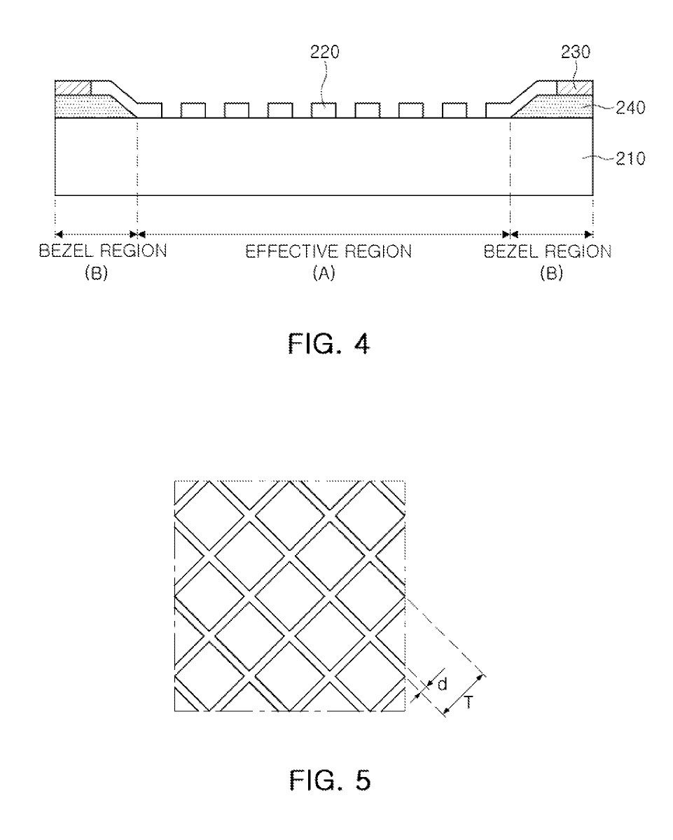

FIG. 4 is a cross-sectional view of the touch panel according to an exemplary embodiment in the present disclosure.

Referring to FIG. 4, the bezel portion 240 is formed on the substrate 210 to be wider than the region having the pad parts 230 formed thereon in order to more reliably shield the opaque pad parts 230. Although the present exemplary embodiment illustrates a case in which the bezel portion 240 is stacked on the substrate 210, the bezel portion 240 may be embedded in the substrate 210. The conductive lines of the electrode parts 220 may be extended to the bezel portion 240 side and may be connected to the pad part 230.

FIG. 5 is a partially-enlarged view of conductive lines according to an exemplary embodiment in the present disclosure. An opening ratio of the electrode part 220 may be defined by a pitch T and a line width d of the conductive line. As the pitch T is large and the line width d is narrow, the opening ratio of the electrode part 220 may be increased. Generally, a relationship between the opening ratio to of the electrode part 220, and the pitch T and the line width d may be represented by the following Equation 1.

$$to = {( \frac{T - d}{T} )}^{2} \qquad [ Equation 1 ]$$

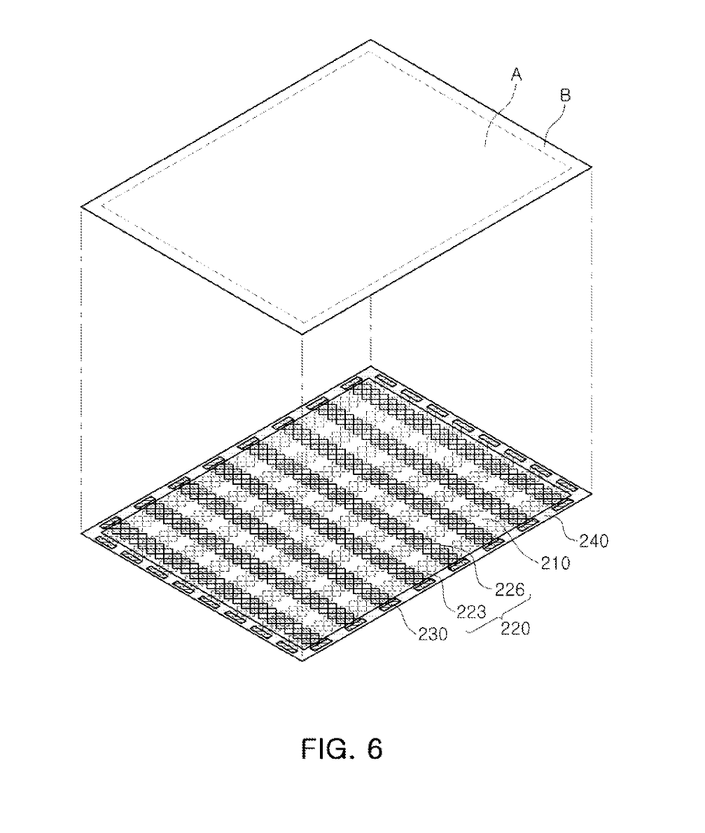

FIGS. 6 through 8 are perspective views illustrating touch panels according to various exemplary embodiments in the present disclosure. In FIGS. 6 through 8, planes illustrated over the touch panel 200 are not actually present, but illustrate regions formed by dividing the substrate 210 to illustrate the opening ratio of the electrode part 220.

Referring to FIG. 6, the electrode parts formed in the effective region A and the bezel region B of the substrate 210 may have different opening ratios. As described above, the effective regions A of the touch panel correspond to those to which the display screen is output and the touch is input. In order to increase transparency of the touch panel and invisibility of the conductive lines, the opening ratio of the electrode part 220 formed in the effective region A may be set to be higher than that of the electrode part 220 formed in the bezel region B. In addition, the bezel region B may have the opening ratio set to be lower than that of the effective regions A to have decreased resistance and prevent the conductive lines from being disconnected due to a step caused by a bezel portion 240 that may be formed in the bezel region B.

In this case, the opening ratio of the electrode part 220 formed in the bezel region B may be 20% to 80% of the opening ratio of the electrode part 220 formed in the effective region A.

The following Table 1 indicates disconnection rates of conductive lines in the bezel region B and line widths of conductive lines in the effective region A, in response to a ratio (B/A) of the opening ratio of the electrode part formed in the bezel region B to the opening ratio of the electrode part formed in the effective region A. In the following Table 1, the line width of the conductive line in the effective region A corresponds to a line width of a conductive line actually manufactured according to the ratio (B/A) of the opening ratios in the case that a target line width of the conductive line is 3 μm.

Referring to the following Table, when the ratio (B/A) of the opening ratios is less than 20%, it could be confirmed that the disconnection ratio of the conductive line in the bezel region B is low, but a difference between the target line width and the actually manufactured line width is significantly generated. In the case that a significant difference in opening ratio is present between the effective region A and the bezel region B, in the case of electrodes provided in the bezel region B, a large amount of portions to be etched may be present while in the case of electrodes provided in the effective region A, a small amount of portions to be etched may be present. As areas in which etching is performed are different, the actually manufactured line width may be wider than the target line width.

In addition, when the ratio (B/A) of the opening ratios is greater than 80%, the target line width and the actually manufactured line width may be equal to each other, but the disconnection ratio of the conductive line in the bezel region B may be sharply increased.

According to an exemplary embodiment, the opening ratio of the electrode part 220 formed in the bezel region B may be set to 20% to 80% of the opening ratio of the electrode part 220 formed in the effective region A, such that the difference between the target line width and the actually manufactured line width may be decreased, and the disconnection of the conductive line in the bezel region B may be prevented.

| | Ratio (B/A) of Opening Ratios | | | | | | | | | |
|---|---|---|---|---|---|---|---|---|---|---|
| | 10% | 20% | 30% | 40% | 50% | 60% | 70% | 80% | 90% | 100% |
| Line Width | 7~10 μm | 5~6 μm | 4 μm | 3.5 μm | 3 μm | 3 μm | 3 μm | 3 μm | 3 μm | 3 μm |
| of Conductive | | | | | | | | | | |
| Line in Effective | | | | | | | | | | |
| Region A | | | | | | | | | | |
| Disconnection Rate | 0% | 0% | 1% | 1% | 3% | 4% | 5% | 7% | 12% | 19% |
| of Conductive | | | | | | | | | | |
| Line in Bezel | | | | | | | | | | |
| Region B | | | | | | | | | | |

Specifically, in the case in which the pitch of the conductive lines is identical in the cases of the effective region A and the bezel region B, the line width of the conductive lines in the bezel region B may be 100% to 400% of the line width of the conductive lines in the effective region A. Since the line width of the conductive lines in the effective region A may be set to 0.5 μm to 6 μm, the line width of the conductive lines in the bezel region B may be set to 0.5 μm to 24 μm.

In a case in which the line width of the conductive lines is identical in the cases of the effective region A and the bezel region B, the pitch of the conductive lines in the bezel region B may be 50% to 100% of the pitch of the conductive lines in the effective region A. Since the pitch of the conductive lines in the effective region A may be set to 20 μm to 500 μm, the pitch of the conductive lines in the bezel region B may be set to 10 μm to 500 μm.

The opening ratios may be differentially set by simultaneously setting the line width and the pitch to be different.

Meanwhile, areas of the effective region A and the bezel region B may be changed by a setting. As an example, the bezel region B may have the area of 1% to 5% of that of the effective region A.

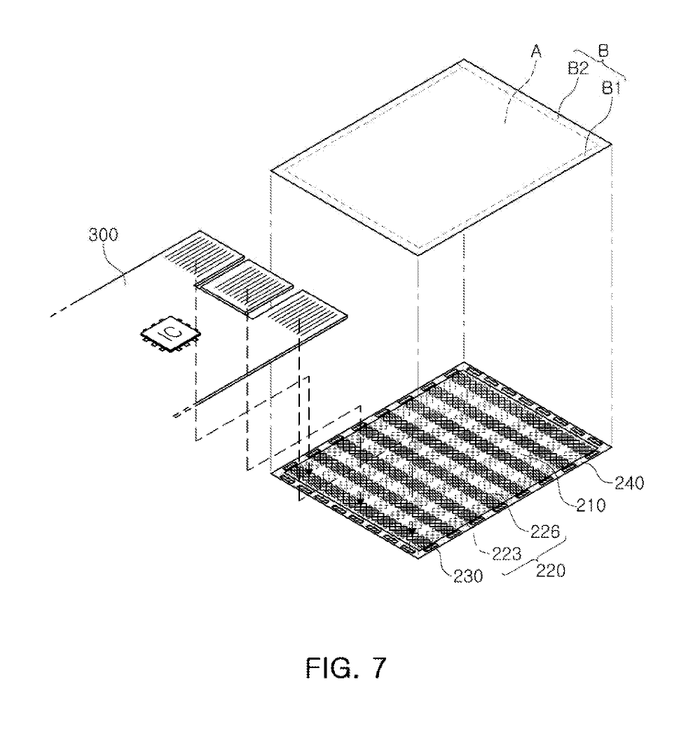

FIG. 7 is a view illustrating the touch panel according to an exemplary embodiment in the present disclosure. In describing the touch panel according to an exemplary embodiment in the present disclosure of FIG. 7, a description for the same portions thereof as those of the touch panel of FIG. 6 will be omitted and portions thereof different from those of the touch panel of FIG. 6 will be mainly described.

Referring to FIG. 7, the bezel region B of FIG. 7 may include a plurality of bezel regions B1 and B2. Specifically, the bezel region B may include a first bezel region B1 and a second bezel region B2. Although not specifically illustrated in FIG. 7, the substrate 210 may be bonded and electrically connected to a flexible printed circuit board 300. Specifically, the wiring patterns and the bonding pads connected to the pad parts 230 may be formed on the bezel portion 240 of the substrate 210. Here, the bonding pads may be electrically connected to the flexible printed circuit board 300 through an anisotropic conductive film (ACF).

The first bezel region B1 may be a region schematically illustrating a portion relatively adjacent to the flexible printed circuit board 10 among the bezel region B and the second bezel region B2 may be a region schematically illustrating a portion relatively distant from the flexible printed circuit board 10 among the bezel region B. The resistance value of the electrode part 220 may be increased as a distance between the electrode part 220 and the flexible printed circuit board 10 is increased. In the case in which the electrode parts 220 of the first bezel region B1 and the second bezel region B2 have the same opening ratio, the electrode part 220 of the second bezel region B2 may have the resistance value higher than that of the electrode part 220 of the first bezel region B1.

According to an exemplary embodiment in the present disclosure, the resistance value may be decreased by setting an opening ratio of the electrode part 220 formed in the second bezel region B2 to be different from an opening ratio of the electrode part 220 formed in the first bezel region B1. Specifically, the electrode part 220 formed in the second bezel region B2 may have the opening ratio lower than that of the electrode part 220 formed in the first bezel region B1. The line width of the conductive lines of the electrode part 220 formed in the second bezel region B2 is set to be thicker than that of the electrode part 220 formed in the first bezel region B1, the pitch of the conductive lines of the electrode part 220 formed in the second bezel region B2 is set to be smaller than that of the electrode part 220 formed in the first bezel region B1, or both of the line width and the pitch are changed, such that the resistance value of the electrode part 220 formed in the second bezel region B2 may be decreased.

Although FIG. 7 illustrates a case in which the bezel region B is divided into the first bezel region B1, having a “ [symbol] ” shape and the second bezel region B2, having an “|” shape, the bezel region B may be divided into various shapes in addition to the above-mentioned shapes. In addition, although FIG. 7 illustrates a case in which the bezel region B is divided into two bezel regions B1 and B2, the bezel region may be divided into three or more regions in addition to the two regions.

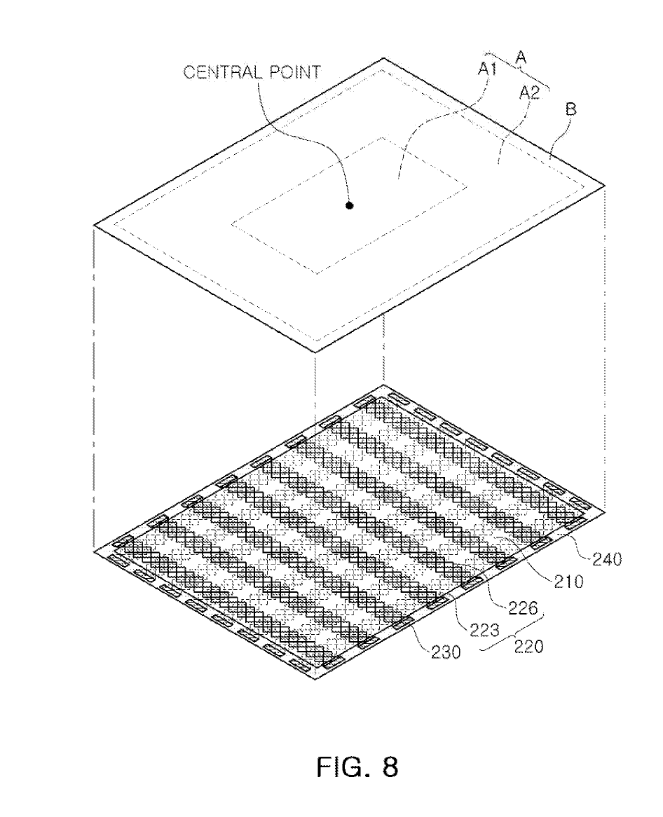

FIG. 8 is a view illustrating the touch panel according to an exemplary embodiment in the present disclosure. In describing the touch panel according to an exemplary embodiment in the present disclosure of FIG. 8, a description for the same portions thereof as those of the touch panel of FIG. 6 will be omitted and portions thereof different from those of the touch panel of FIG. 6 will be mainly described.

Referring to FIG. 8, the effective region A of FIG. 7 may include a plurality of effective regions A1 and A2. The plurality of effective regions A1 and A2 may have predetermined areas depending on a distance between the plurality of effective regions A1 and A2 and the central point of the substrate 210. In this case, the plurality of respective effective regions A1 and A2 may have different opening ratios. In this case, a region having a distance close to the central point may have the opening ratio higher than that of a region having a distance distant from the central point.

Specifically, the effective region A may include a first effective region A1 and a second effective region A2. In this case, the electrode parts 220 formed in the first effective region A1 and the second effective region A2 may have different opening ratios. The electrode part 220 formed in the first effective region A1 may have the opening ratio higher than that of the electrode part 220 formed in the second effective region A2. In this case, the electrode part 220 formed in the second effective region A2 may have the opening ratio higher than that of the electrode part 220 formed in the bezel region B.

The opening ratio of the electrode part 220 formed in the first effective region A1 positioned at the central point of the substrate 210 is set to be higher than that of the electrode part 220 formed in the second effective region A2 distant from the central point, such that transparency of the touch panel and invisibility of the conductive lines in the central portion of the effective region A may be increased.

Although FIG. 8 illustrates a case in which the effective region A is divided into the first effective region A1 and the second effective region A2 having a quadrangular shape, the effective region A may be divided into various shapes such as a circular shape, and the like in addition to the above-mentioned shape. In addition, although FIG. 8 illustrates a case in which the effective region A is divided into two effective regions A1 and A2, the effective region may be divided into three or more regions in addition to the two regions.

Further, without dividing the effective region A and the bezel region B, the opening ratio may be set to be gradually increased from the bezel region side (an edge) of the substrate 210 to the central point of the substrate 210. In this case, the opening ratio may be changed within a range of 10% to 99%, the line width may be changed within a range of 0.5 μm to 24 μm, and the pitch may be changed within a range of 10 μm to 500 μm.

As set forth above, according to exemplary embodiments in the present disclosure, transparency of the touch panel in the effective region may be improved, and the disconnection of the conductive lines in the bezel region may be prevented and the resistance value thereof may be decreased.

While exemplary embodiments have been shown and described above, it will be apparent to those skilled in the art that modifications and variations could be made without departing from the scope of the invention as defined by the appended claims.

What is claimed is:

1. A touch panel, comprising:
a substrate; and
electrode parts including a plurality of electrodes disposed on the substrate,
wherein the electrode parts include a plurality of conductive lines in a mesh pattern, and have different opening ratios for a plurality of respective regions of the substrate.

2. The touch panel of claim 1, wherein the plurality of regions include an effective region and a bezel region, and
the opening ratio of the electrode part in the effective region is greater than the opening ratio of the electrode part in the bezel region.

3. The touch panel of claim 2, wherein the opening ratio of the electrode part in the bezel region is 20% to 80% of the opening ratio of the electrode part in the effective region.

4. The touch panel of claim 1, wherein the opening ratios of the electrode parts are determined by at least one of a pitch and a line width of the conductive lines.

5. The touch panel of claim 2, wherein the conductive lines of the electrode part formed in the bezel region have a line width 100% to 400% of a line width of the conductive lines of the electrode part formed in the effective region.

6. The touch panel of claim 5, wherein the line width of the conductive lines of the electrode part formed in the effective region is 0.5 μm to 6 μm.

7. The touch panel of claim 5, wherein the line width of the conductive lines of the electrode part formed in the bezel region is 0.5 μm to 24 μm.

8. The touch panel of claim 2, wherein a pitch of the conductive lines of the electrode part formed in the bezel region is 50% to 100% of a pitch of the conductive lines of the electrode part formed in the effective region.

9. The touch panel of claim 8, wherein the pitch of the conductive lines of the electrode part formed in the effective region is 20 μm to 500 μm.

10. The touch panel of claim 8, wherein the pitch of the conductive lines of the electrode part formed in the bezel region is 10 μm to 500 μm.

11. The touch panel of claim 2, wherein the bezel region has an area of 1% to 5% of an area of the effective region.

12. The touch panel of claim 2, wherein the bezel region includes at least two bezel regions and the opening ratios of the electrode parts formed in the at least two bezel regions are respectively determined depending on distances between the electrode parts and a flexible printed circuit board obtaining sensing signals.

13. The touch panel of claim 12, wherein the opening ratios of the electrode parts formed in the at least two bezel regions are determined to be lower as the distance between the electrode parts and the flexible printed circuit board is increased.

14. The touch panel of claim 12, wherein the effective region includes at least two effective regions and the opening ratios of the electrode parts formed in the at least two effective regions are respectively determined depending on distances between the electrode parts and a central point of the substrate.

15. The touch panel of claim 14, wherein the opening ratios of the electrode parts formed in the at least two effective regions are determined to be higher as the distances between the electrode parts and the central point of the substrate are decreased.

16. The touch panel of claim 14, wherein the at least two effective regions have predetermined areas depending on the distances between the at least two effective regions and the central point of the substrate.

17. The touch panel of claim 1, wherein the conductive lines are formed of one of silver (Ag), aluminium (Al), chromium (Cr), nickel (Ni), molybdenum (Mo), and copper (Cu) or an alloy containing at least two of Ag, Al, Cr, Ni, Mo, and Cu.

18. The touch panel of claim 1, wherein the substrate is formed of at least one of polyethylene terephtalate (PET), polycarbonate (PC), polyethersulfone (PES), polyimide (PI), polymethylmethacrylate (PMMA), cyclo-olefin polymers (COP), soda glass, and tempered glass.

19. The touch panel of claim 1, wherein the opening ratios satisfy the following Equation with respect to a pitch and a line width of the conductive lines.
$$to = {( \frac{T - d}{T} )}^{2} \qquad [ Equation ]$$
Where, to is an opening ratio,
T is a pitch, and
d is a line width.

20. The touch panel of claim 1, wherein the plurality of electrodes include:
a plurality of first electrodes extending in a first axial direction, and
a plurality of second electrodes extending in a second axial direction intersecting with the first axial direction.

21. The touch panel of claim 1, wherein the plurality of first electrodes and the plurality of second electrodes are formed on the same surface or different surfaces of the substrate.

22. A touch panel, comprising:
a substrate; and
electrode parts including a plurality of electrodes formed on the substrate,
wherein the electrode parts include conductive lines formed in a mesh pattern, and the conductive lines have an opening ratio increased from an edge of the substrate towards a center thereof.

23. The touch panel of claim 22, wherein the opening ratio of the conductive lines formed in a plurality of mesh patterns is changed within a range of 10% to 99%.

24. The touch panel of claim 22, wherein the conductive lines have a line width changed within a range of 0.5 μm to 24 μm.

25. The touch panel of claim 22, wherein the conductive lines have a pitch changed within a range of 10 μm to 500 μm.
